(19) United States
(12) Patent Application Publication
(10) Pub. No.: US 2026/0354137 A1
(43) Pub. Date: Nov. 5, 2026

(54) POLYCRYSTALLINE SILICON CARBIDE SUPPORT FOR A SUBSTRATE INTENDED TO RECEIVE POWER SEMICONDUCTOR DEVICES AND SUBSTRATE COMPRISING SUCH A SUPPORT

(71) Applicant: Soitec, BERNIN (FR)

(72) Inventors: Thierry Boudet, BERNIN (FR); Hugo Biard, BERNIN (FR)

(21) Appl. No.: 19/487,075

(22) PCT Filed: Jun. 4, 2024
(86) PCT No.: PCT/EP2024/065338

§ 371 Date: Nov. 24, 2025

(30) Foreign Application Priority Data
Jun. 26, 2023 (FR) FR2306631

(51) Int. Cl. H10W 10/10; H10D 30/47; H10D 62/824; H10P 90/00; H10W 10/00; H10W 10/40

(52) U.S. Cl. CPC H10W 10/181; H10D 30/475; H10D 62/824; H10P 90/1914; H10W 10/041; H10W 10/40

(57) ABSTRACT

A polycrystalline silicon carbide support for a substrate intended to receive a power semiconductor device has a first front face and a second rear face, and comprises a first surface layer disposed directly under the first front face and having resistivity that is greater than or equal to 1 ohm.cm, and a second rear surface layer disposed directly under the rear face and having resistivity that is less than 1 ohm.cm.

### CROSS-REFERENCE TO RELATED APPLICATIONS

This application is a national phase entry under 35 U.S.C. § 371 of International Patent Application PCT/EP2024/065338, filed Jun. 4, 2024, designating the United States of America and published as International Patent Publication WO 2025/002734 A1 on Jan. 2, 2025, which claims the benefit under Article 8 of the Patent Cooperation Treaty of French Patent Application Serial No. FR2306631, filed Jun. 26, 2023.

### TECHNICAL FIELD

The present disclosure relates to substrates intended to receive semiconductor devices, notably devices for applications requiring high electrical power. This can involve devices based on III-N materials, such as gallium nitride. The present disclosure also relates to a support particularly adapted to form such a substrate.

### BACKGROUND

Some of the applications of transistors based on III-N materials, of the HEMT (“High Electron Mobility Transistor”) type are in the field of managing high electrical power, for example, such as switches in power converters.

As schematically shown in FIG. 1, such a component 1 conventionally uses:
a substrate 2, which typically can be a silicon, sapphire or silicon carbide wafer;
a buffer layer 3, generally doped in order to be semi-insulating, formed on the substrate 2;
a heterojunction made up of a GaN channel layer 5 and an AlGaN barrier layer 6 successively formed on the buffer layer 3;
source S, drain D and gate G electrode structures on/in the heterojunction;
a metal sheet M in ohmic contact with the rear face of the substrate 2. The metal sheet M can be the copper lead frame of a housing for a semiconductor chip. An adhesion layer B, for example, a silver sintering paste, can be used to make the rear face of the substrate 2 reliably adhere to the metal sheet M.

The metal sheet M helps to promote the discharge of the heat generated at the heterojunction when the device is operating. Generally, the source electrode S is electrically connected to the substrate 2, so as to prevent the potential of this substrate from remaining floating. The electrically conducting state of the transistor between the source S and the drain D is controlled by the voltage applied to the gate G. In the case of power applications, the voltage VDs applied across the terminals of the source S and drain D electrodes can then reach a few hundred volts to several thousand volts when the transistor is turned off. The leakage current flowing between the source S and the drain D in the off state is low, on the order of a few nanoamperes. On the contrary, in the on state, several amperes can flow between the source S and the drain D. Furthermore, switching between the on state and the off state is very fast, on the order of a few nanoseconds.

However, several problems limit the dissemination of this technology.

As has been seen, in the off state, a high voltage is applied across the terminals of the source S and drain D electrodes. This leads to the formation of an electric field, the lines of which penetrate very deeply into the buffer layer 3 and the substrate 2. An electric field then develops between the drain electrode D and the substrate 2, notably in the thickness of the buffer layer 3, and between the source S and the drain D. In order to prevent the intensity of this field from exceeding the critical value (called breakdown field) beyond which it can no longer be supported by the material, provision must be made for the drain D and the source S to be separated by a sufficient distance so that, for a given voltage V_{DS}, the field intensity E=V_{DS}/d is less than the breakdown field. Similarly, provision can be made to provide a buffer layer 3 that is thick enough so that the value of the electric field at the interface between the buffer layer 3 and the substrate 2 is less than the permissible limit for the relevant materials.

It is relatively easy to select the distance separating the drain electrode D from the source S when designing the transistor. Thus, for a voltage VDs on the order of 400 V to 2,000 V, a distance on the order of 5 to 20 microns can be selected. However, there are limits to increasing this distance, as it tends to increase the size of the HEMT device and therefore makes it more expensive and less compact.

Providing a component 1 with a sufficiently thick buffer layer 3 of III-N materials (on the order of 3 microns or more) is, however, much more difficult, notably when the substrate 2 is selected from large-scale silicon (200 mm diameter) rather than sapphire, for availability and cost reasons. This is due to the difference between the thermal expansion coefficient of silicon and that of the III-N material that forms the buffer layer 3. The buffer layer 3 is produced by high temperature deposition onto the silicon substrate 2, and returning to room temperature subjects the buffer layer 3 to very high stresses, which can lead to cracking, or even breakage, of the substrate if the stresses are too great. It is generally difficult to provide a buffer layer 3 that is more than 3 microns thick on a silicon substrate 2 in the form of a 200 mm wafer.

Naturally, an attempt could be made to replace the silicon substrate 2 with a substrate with a thermal expansion coefficient closer to that of the material of the buffer layer 3 to overcome this constraint. This could involve using a silicon carbide substrate 2, for example. However, apart from the fact that this material in its crystalline form is particularly scarce and expensive, it also must be metallized and treated to form an ohmic contact with the metal sheet M. The document entitled, “Ohmic contacts to SiC,” in the International Journal of High Speed Electronics and Systems, Vol. 15, No. 04, pp. 781-820 (2005), states that metal layer-SiC contact is generally non-ohmic immediately after the metal layer has been deposited. This interface then needs to be thermally treated, for example, using a laser, in order to promote the formation of silicides, carbides or ternary phases, making the contact effectively ohmic. Simplifying how the device is housed would be beneficial.

U.S. Patent Application Publication No. 2013/0112997A1, European Patent No. EP3351660B1, and U.S. Patent Application Publication No. 2005/0269671 A1 propose substrates comprising polycrystalline silicon carbide supports.

### BRIEF SUMMARY

An aim of the present disclosure is to propose a support for a substrate intended to receive a power semiconductor device that at least partly addresses these problems. More specifically, an aim of the present disclosure is to propose a support for a substrate capable of receiving a relatively thick buffer layer, preferably having a thickness that is greater than or equal to 5 microns, and that can be simply integrated into a housing, without having to apply heat treatment to the face that receives the adhesion layer. An aim of the present disclosure is to provide a substrate that uses such a support and a semiconductor device formed on/in such a substrate.

In order to achieve one of these aims, the subject matter of the present disclosure proposes a polycrystalline silicon carbide support for a substrate intended to receive a power semiconductor device. The support comprises a first face, denoted “front face,” and a second face opposite the first and denoted “rear face.” The support comprises:
a first surface layer disposed directly under the front face and having resistivity that is greater than or equal to 1 ohm.cm; and
a second surface layer disposed directly under the rear face and having resistivity that is strictly less than 1 ohm.cm.

According to other advantageous and non-limiting features of the present disclosure, taken individually or according to any technically feasible combination:
the minimum thickness of the second layer is 10 or more microns;
the second layer has a concentration of n-type dopants, such as nitrogen, that is greater than 10²⁰ at/cm³;
the concentration of n-type dopants monotonically increases from the front face to the second surface layer;
the first layer is not intentionally doped or has a vanadium concentration that is greater than 10¹⁵ at/cm³;
the total thickness of the support, between the first face and the second face, ranges between 200 microns and 1 mm;
the support is in the form of a circular wafer, advantageously with a 200 mm diameter.

According to another aspect, the subject matter of the present disclosure proposes a substrate intended to receive a semiconductor device comprising a support as described above and a seed layer, transferred onto the front face of the support.

According to other advantageous and non-limiting features of this aspect of the present disclosure, taken alone or according to any technically feasible combination:
the seed layer is made up of gallium nitride, silicon carbide, sapphire or silicon (1,1,1);
the substrate comprises a dielectric bonding layer disposed between, and in contact with, the support and the seed layer, preferably a dielectric bonding layer made of silicon nitride;
the seed layer is in direct contact with the substrate;
a gallium nitride-based buffer layer, which preferably is semi-insulating, is disposed on the seed layer;
the buffer layer is more than 3 microns thick, preferably more than 5 microns thick, and even more preferably ranges between 5 microns and 10 microns thick;
the substrate comprises a heterojunction disposed on the buffer layer, the heterojunction comprising a channel layer and a barrier layer and is capable of forming a 2D electron gas.

According to yet another aspect, the present disclosure proposes a semiconductor component comprising a substrate as described above and a source structure, a drain structure and a gate structure disposed on the heterojunction.

Advantageously, a metal sheet is disposed under the rear face of the substrate, in ohmic contact with a metal layer deposited onto the second surface layer. An adhesion layer, such as a silver sintering paste layer, can be disposed between the metal sheet and the metal layer deposited onto the second surface layer.

### BRIEF DESCRIPTION OF THE DRAWINGS

Further features and advantages of the present disclosure will become apparent from the following detailed description of the present disclosure, with reference to the appended figures, in which:

FIG. 1 shows a substrate provided with an HEMT transistor according to the prior art

FIGS. 2A and 2B show two substrates intended to receive semiconductor devices according to the present disclosure;

FIG. 3 shows a semiconductor component formed from a substrate according to the present disclosure.

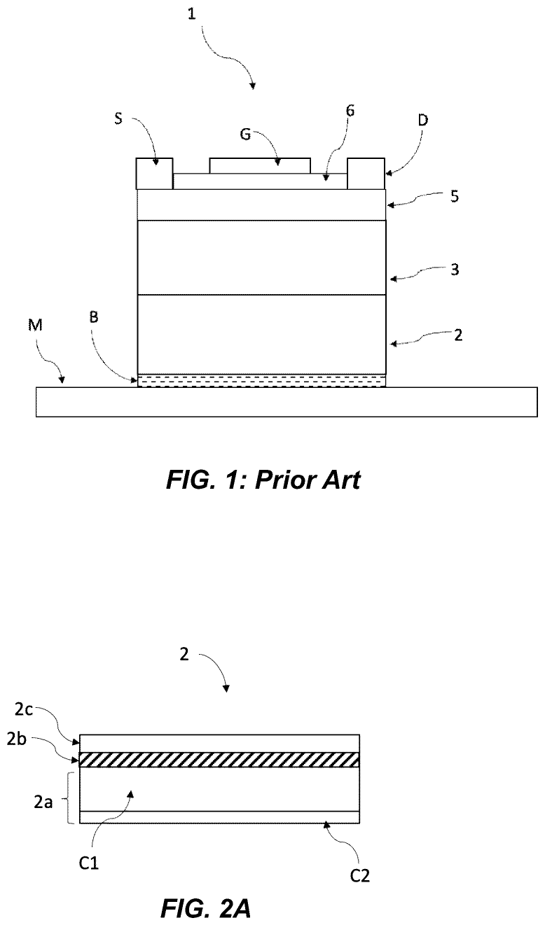

### DETAILED DESCRIPTION

In order to simplify the following description, the same reference signs are used for elements that are identical or that provide the same function in the various embodiments of the present disclosure or in the disclosure of the prior art.

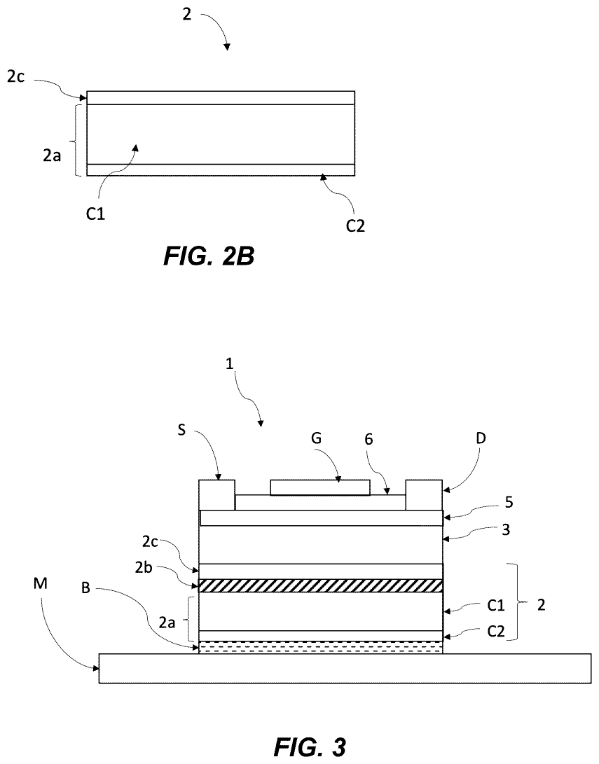

FIGS. 2A and 2B show two embodiments of a substrate 2 intended to receive a power semiconductor device in accordance with the present disclosure. As briefly disclosed in the introduction to this disclosure, this substrate 2 is intended to receive at least one device comprising a buffer layer made of III-N material that is several microns thick, a heterojunction comprising a channel layer and a barrier layer on the buffer layer, and source, drain and gate structures disposed on the heterojunction.

The substrate 2, when it is still devoid of devices, is advantageously in the form of a circular wafer, the diameter of which is standardized so that it can be handled by standard equipment in the semiconductor industry. Advantageously, a 200 mm diameter is selected.

After the steps of forming the devices and the singularization thereof, as is well known per se, chips are formed that are intended to integrate housings for forming a semiconductor component. The substrate 2, when it is incorporated into a chip, then assumes the form of a rectangular parallelepiped with sides of the order of mm or cm.

### General Presentation of the Substrate 2

Irrespective of the shape adopted by the substrate 2, in very general terms it comprises a support 2a and a seed layer 2c transferred onto the support 2a. In the embodiment of FIG. 2A, a dielectric bonding layer 2b is disposed between, and in contact with, the support 2a and the seed layer 2c. In the embodiment of FIG. 2B, the substrate 2 is devoid of a dielectric bonding layer and the seed layer 2c is directly transferred onto the support 2a, in contact with this support 2a.

The support 2a is entirely made up of polycrystalline silicon carbide. It comprises a first face, denoted “front face,” and a second face opposite the first and denoted “rear face.” The seed layer 2c is transferred onto the front face of the support 2a, either directly or via the dielectric bonding layer 2b. The main function of the support 2a is to mechanically support the remainder of the stack leading to the formation of a functional semiconductor component, as will be disclosed in a subsequent section of this detailed description. To this end, the thickness thereof, measured between its front face and its rear face, is relatively high, typically ranging between 200 microns and 1 mm.

The function of the seed layer 2c, for its part, is to provide an exposed surface of the substrate 2 that is capable of receiving the buffer layer 3 of the device. The nature of this seed layer 2c is therefore selected so as to provide a lattice parameter adapted to that of the III-N material forming the buffer layer 3, typically gallium nitride, to facilitate its epitaxial growth on the substrate 2. This therefore can involve gallium nitride, silicon carbide, sapphire or silicon (1,1,1), in all cases in their monocrystalline form. This seed layer 2c does not need to be thick, as only its surface properties are exploited, and a relatively low thickness of less than 2 microns is therefore selected.

The purpose of the dielectric bonding layer 2c is to facilitate the manufacture of the substrate 2, as will be disclosed hereafter. It is preferable for a dielectric material with a good thermal diffusion coefficient to be selected, such as silicon nitride, and for its thickness to be minimized, preferably less than 1 micron, so as not to affect the thermal properties of the substrate 2, as will be explained hereafter.

It should be noted that the seed layer 2c is much thinner than the thickness of the support 2a. As a result, and due to the compliance effect, it undergoes the deformations imposed thereon by the support 2a, when, for example, the substrate 2 is exposed to significant temperature variations of several hundred degrees, as is the case during the epitaxial formation of the buffer layer 3. In other words, the deformation of the substrate 2 generated by its exposure to a significant temperature variation is dictated by the behavior of the support 2a. The thickness of the seed layer 2 c is preferably selected so as to be relatively low, less than 2 microns as already stated, to promote this compliance effect.

It also should be noted that the polycrystalline silicon carbide from which the support 2a is formed has a thermal expansion coefficient close to that of the III-N material forming the buffer layer 3, notably when this buffer layer 3 is made of gallium nitride. Also, after the high-temperature epitaxial formation of the buffer layer 3, and when the substrate 2 provided with this buffer layer 3 is brought back to room temperature, minimal stresses develop in the substrate 2. It is therefore possible to form a buffer layer 3 that is much thicker than that which can be formed on a silicon substrate of the prior art. Notably, a buffer layer 3 can be formed that is at least 3 microns thick, preferably that is more than 5 microns thick and even more preferably that ranges between 5 microns and 10 microns thick.

Finally, the polycrystalline silicon carbide from which the support 2a is formed (which represents most of the substrate 2), has thermal diffusion properties that allow the heat produced in the device to be dissipated efficiently. By way of a reminder, since this device is preferably designed to deal with a significant amount of electrical power, it tends to heat up, and the heat that is produced needs to be discharged to avoid affecting the correct operation thereof. Thus, the thermal diffusion coefficient of polycrystalline silicon carbide is approximately three times greater than that of the silicon forming a substrate of the prior art. By improving the thermal conductivity of the substrate 2 compared with a substrate of the prior art, it is also possible to increase the power density processed by the device.

According to an important feature of the support 2a, it comprises a first surface layer C1, disposed directly under the front face, which has resistivity that is greater than or equal to 1 ohm.cm, and advantageously that is greater than 10³ ohm.cm. In the presence of a high intensity electric field with lines that extend into the depth of the substrate 2, and notably into this first surface layer C1 of the support, the resistive nature of this first surface layer C1 allows the breakdown voltage to be removed. The device can therefore withstand high drain-source voltages, in excess of 1,000 V, without risking any damage to the device.

In order to obtain these resistivity values, the first layer C1 is intrinsic, i.e., it is not intentionally doped. Alternatively, it can be doped with vanadium at a concentration of more than 10¹⁵ at/cm³, to further increase its resistivity.

The support 2a also comprises a second surface layer C2 disposed directly under the rear face. This second surface layer C2 has a resistivity of strictly less than 1 ohm.cm, and can be less than 50 milliohm. cm or 10 milliohm. cm. This low resistivity, which can be obtained by n-type doping in a concentration of dopants (for example, nitrogen) that is greater than 10²⁰ at/cm³, allows the rear face of the substrate to be provided with almost metallic behavior, and therefore allows a layer of metal or metal alloys to be received, by deposition, without requiring heat treatment before applying a method for assembling this face on a metal sheet, during the encasing step.

This second surface layer C2 does not need to be very thick, but it nevertheless is more than 10 microns thick.

Preferably, the first layer C1 extends into the depth of the substrate 2 as far as the second highly doped layer C2. Of course, a transition zone can exist between these two layers C1, C2, to control the doping gradient required for this transition. Notably, it is possible to contemplate that the concentration of n-type dopant in the support 2a monotonically increases from the front face to the second surface layer C2.

However, in all cases, and irrespective of the way in which the dopants are distributed in the thickness of the support 2a, the support has a first surface layer C1 disposed directly under the front face, as close as possible to the device, which is resistive or highly resistive in order to counter the effects of the electric fields that can develop therein. The support 2a also has a second surface layer C2, disposed directly under the rear face, with very low resistivity in order to provide it with metallic behavior that promotes the reliable assembly thereof on a metal sheet when encasing the device.

### Manufacturing the Polycrystalline Silicon Carbide Substrate

Manufacturing a polycrystalline silicon carbide substrate according to the present disclosure, and therefore having the first and second surface layers C1, C2, uses a chemical vapor deposition (CVD) technique. This technique uses a gas mixture comprising at least one silicon precursor gas (such as a silane or a chlorosilane) and/or at least one carbon precursor gas (such as an alkane or an alkene), and/or at least one silicon and carbon precursor gas (such as methyltrichlorosilane, abbreviated to MTCS) in order to form the bulk part of the support 2a.

It also uses at least one n-type doping gas to form at least the second surface layer C2. In the case of nitrogen doping of this second surface layer C2, the doping gas can be NH₃, N₂H₄, N₂, for example.

For vanadium doping of the first surface layer C1, if such doping is provided, a vanadium chloride doping gas (VCl2, for example) can be used.

These gases can be diluted in a carrier gas, which can be a reducing gas such as hydrogen and/or an inert gas such as argon. The polycrystalline silicon carbide layer is formed from this gas mixture on a substrate, called “growth” substrate.

The gaseous mixture is admitted into a reactor at high temperature where the precursor gases are decomposed and react on the surface of the growth substrate, preferably made of purified fine-grained isostatic graphite, in order to form a layer of polycrystalline silicon carbide, for example, of 3C polytype, the mechanical and thermal resistance properties, the thermal expansion coefficient and the purity of which are perfectly adapted to its use as a support 2a for the substrate 2. 3C polytype also can be doped with nitrogen at very high levels, of the order of 10²⁰ atoms/cm³, and thus can have resistivity of less than 10 m ohm.cm.

The reactor temperature during the CVD deposition of the silicon carbide must be between approximately 1,000 °C and approximately 1,600 °C, preferably between approximately 1,100 °C and approximately 1,400 °C, or even between 1,200 °C and approximately 1,400 °C. Within this temperature range, the deposition rates can vary over fairly wide ranges, from a micron/hr to more than 100 micron/hr. Advantageously, the total pressure in the reactor does not exceed 350 mbar, or even 300 mbar.

In order to form a support 2a according to the present disclosure, the flow of n-type doping gas is controlled so as to form, at the start of the growth process, optionally after the formation of a seed thickness on the graphite surface, a layer of doped polycrystalline silicon carbide that is thick enough to eventually form, after all the finishing steps described hereafter, the second surface layer C2 of the support 2a. This can involve forming an n-type doped layer during this growth process, which is 2 to 10 times thicker than the thickness expected in this support, which by way of a reminder is typically greater than 10 microns after any thinning of the substrate.

During this deposition phase, after forming the highly n-doped thickness, the flow of n-type doping gas can be interrupted to form the remainder of the thickness of intrinsic polycrystalline silicon carbide, which is not intentionally doped. Alternatively, a flow of vanadium-based doping gas can be circulated to further increase the resistivity of the material intended to form the first surface layer C1.

On completion of this deposition phase, the graphite growth substrate, coated with a polycrystalline silicon carbide deposition layer, is machined and then oxidized in air, typically at 900 °C, to remove any graphite residue and to provide a rough disc of polycrystalline silicon carbide. It should be noted that the graphite also could be removed using purely mechanical machining techniques or even basically by burning/oxidation.

It should be noted that it is possible, during the deposition phase, for a very thick polycrystalline silicon carbide to be formed to form an ingot of material. Slices then can be cut from this ingot, with each slice forming a rough silicon carbide disc. In this approach, heavily n-doped interlayers (which will be used to form second surface layers C2) will be carefully inserted between intrinsic or vanadium-based doped layers (which will be used to form first surface layers C1) when growing the ingot. The ingot will be cut at positions that allow, after all the finishing steps described hereafter, supports 2a to be formed in accordance with the present disclosure.

In any case, a rough polycrystalline silicon carbide disc resulting from the deposition phase is then mechanically and thermally treated to form the support 2a with the selected dimensions. This can involve thinning steps using coarse and then fine grinding. These steps can be followed by a polishing step to provide a satisfactory surface finish in terms of roughness. These grinding or polishing steps, which are known in the prior art, are notably intended for removing enough thickness from the side of the disc face that was in contact with the graphite, to remove the initial crystal growth zone, which generates high stresses. They also allow, by removing material from both sides of the rough disc, a polycrystalline silicon carbide support 2a to be obtained in the form of a wafer, for example, a wafer with a diameter of 200 mm and a thickness typically ranging between 350 microns and 500 microns, but which can extend, for example, between 200 nm and 1 mm.

### Manufacturing the Substrate 2

In very general terms, the substrate 2 can be produced using a manufacturing method by transferring a seed layer onto the support 2a, the preparation of which has been described above. Such a transfer method comprises:
assembling, optionally via a dielectric bonding layer 2b, the first face of the support 2a and a main face of a donor substrate to form an intermediate structure;
removing part of the donor substrate from the intermediate structure to define the seed layer 2c, transferred onto the support 2a.

The dielectric bonding layer 2b can be formed, by deposition and prior to the assembly step, on the donor substrate or on the front face of the support 2a or partly on either of these elements. The dielectric bonding layer 2b thus can be produced using an LPCVD (Low Pressure Chemical Vapour Deposition) or PECVD (Plasma Enhanced Chemical Vapour Deposition) technique. As already stated, this layer is advantageously made of silicon nitride, for thermal diffusivity reasons.

The term “donor substrate” is understood to mean a substrate made of the material of the seed layer 2c, or comprising a surface thickness of this material. Thus, the donor substrate can be formed, by way of an example, from a solid substrate of monocrystalline gallium nitride, of monocrystalline silicon (1,1,1), of sapphire, or of monocrystalline silicon carbide. By way of an additional example, the donor substrate can assume the form of a composite substrate formed by a first substrate that supports a thickness (at least equal to that of the seed layer 2c) of the material intended to form the seed layer. This notably can be a thickness of a III-N material such as gallium nitride formed on a silicon substrate (1,1,1).

The assembly step of the layer transfer manufacturing method is advantageously implemented by molecular adhesion. As is well known per se, during a molecular adhesion method, the first face of the support 2a and a face of the donor substrate (optionally both covered with a dielectric layer intended to form the dielectric bonding layer 2b), which are perfectly clean, flat and smooth, are brought into close contact in order to promote the development of molecular bonds, for example, of the Van der Waals or covalent type. The assembly of the two bodies is then achieved without using an adhesive. These bonds can be strengthened by applying heat treatment to the intermediate structure thus formed. When the intention is to form a substrate 2 devoid of a dielectric bonding layer, the first face of the support 2a and the face of the donor substrate are not provided with a dielectric layer and are brought into close contact directly with each other.

The step of removing part of the donor substrate can be carried out by chemical-mechanical thinning of this substrate.

Preferably, however, the substrate 2 is manufactured by applying Smart Cut™ technology, according to which a layer intended to form the seed layer 2c is delimited via a weakened plane formed by implanting “light” species (typically hydrogen and/or helium) in the donor substrate. After the assembly step, this layer is removed from the donor substrate by fracturing in the vicinity of the weakened plane and is thus transferred onto the support 2a.

Whether the removal of a portion of the thickness of the donor substrate is carried out by thinning or by fracturing, it is possible to apply any type of finishing treatment to the substrate thus formed to adapt the seed layer 2c to thickness, thickness uniformity or roughness specifications or to any other type of specifications.

In the substrate 2 thus formed, the rear face of the support 2a, under which the second surface layer C2 is disposed, also forms the rear face of the substrate. The first surface layer C1, for its part, is disposed directly under the seed layer 2c (or directly under the dielectric bonding layer 2b, when this layer is present).

It should be noted that when the material of the donor substrate is a polar material, then a dual transfer of the seed layer 2c taken therefrom needs to be carried out, initially by transferring this seed layer 2c to an intermediate substrate and then, during a second transfer phase, transferring it to the polycrystalline silicon carbide support 2a. In this way, the seed layer 2c has its initial polarity on this support 2a. This is notably the case when the donor substrate comprises gallium nitride, with this material having, in its most widely available form, a gallium face, the exposure of which is generally desired, and a nitrogen face.

### Manufacturing the Semiconductor Component

The substrate 2, in the form of a wafer, is used to form at least one semiconductor component. Thus, and as disclosed in a previous section and illustrated in FIG. 3, a buffer layer 3 based on III-N material is formed by epitaxy on the exposed face of the seed layer 2c of the substrate 2. Preferably, the buffer layer 3 is doped to make it semi-insulating. This can involve, for example, carbon doping, the concentration of which in the main layer can range between 5×10¹⁸ and 5×10¹⁹ at/cm³. It also can be another form of p-type doping, for example, iron or magnesium.

Provision can be made to place one or more interlayers, for example, made of AlGaN or, more generally, of AlInGaN, in the buffer layer 3, which is mainly made of gallium nitride. In any case, the lattice parameter of the seed layer 2c and the thermal expansion coefficient of the polycrystalline silicon carbide support 2a are particularly adapted to the nature of the material of the buffer layer 3 made of III-N material. It is therefore possible to form a relatively high thickness of this buffer layer 3 on the substrate 2, for example, a thickness of more than 3 microns, preferably of more than 5 microns and even more preferably ranging between 5 microns and 10 microns.

In a subsequent step of preparing the semiconductor component 1, a heterojunction is formed on the buffer layer 3. As is well known, such a heterojunction combines at least one channel layer 5 (for example, made of GaN) and a barrier layer 6 (for example, made of AlGaN). A 2D electron gas is likely to develop at the interface of these two layers. A source structure S, a drain structure D and a gate structure G are then disposed on the heterojunction.

It is possible to electrically connect the source structure S to the second surface layer C2 to use the surface layer C2 as a ground plane for the semiconductor component 1.

In some cases, provision can be made to thin the substrate 2, by removing a thickness from the support 2a on the side of the second surface layer C2. However, care must be taken to maintain a sufficient thickness for this layer C2 that is greater than or equal to 10 microns.

In a subsequent step, a metal layer M is formed on the rear face of the support 2a, in contact with the second surface layer C2. This metal layer M can be of any suitable type, for example, titanium, aluminum, nickel, gold or a stack formed by these materials. Due to the high doping of the second surface layer C2 and its low resistivity, the contact with the metal layer is ohmic, without having to thermally treat this interface, which is a particularly advantageous feature of a support according to the present disclosure.

A large number of devices is usually collectively formed on the substrate 2 in the form of wafers. These devices are then singulated by cutting the wafer they are resting on to form semiconductor chips. These chips are encased to form semiconductor components 1, assembled on a metal sheet M using an adhesive, such as a silver sintering paste, forming an adhesion layer B that is particularly reliable for a power component.

Of course, the present disclosure is not limited to the embodiments described, and alternative embodiments can be used without departing from the scope of the invention as defined by the claims.

1. A polycrystalline silicon carbide support for a substrate intended to receive a power semiconductor device, the support comprising a first front face, and a second rear face opposite the first front face, the polycrystalline silicon carbide support comprising:
a first surface layer disposed directly under the first front face and having resistivity that is greater than or equal to 1 ohm.cm; and
a second surface layer disposed directly under the second rear face and having resistivity that is less than 1 ohm.cm.

2. The polycrystalline silicon carbide support of claim 1, wherein the second surface layer is 10 or more micrometers thick.

3. The polycrystalline silicon carbide support of claim 1, wherein the second surface layer has a concentration of n-type dopants that is greater than 10²⁰ at/cm³.

4. The polycrystalline silicon carbide support of claim 3, wherein the concentration of n-type dopants monotonically increases from the first front face to the second surface layer.

5. The polycrystalline silicon carbide support of claim 1, wherein the first surface layer is not intentionally doped or has a vanadium concentration that is greater than 10¹⁵ at/cm³.

6. The polycrystalline silicon carbide support of claim 1, wherein the polycrystalline silicon carbide support has a total thickness, between the first front face and the second rear face, of between 200 micrometers and 1 mm.

7. The polycrystalline silicon carbide support of claim 1, wherein the polycrystalline silicon carbide support is in the form of a circular wafer.

8. A substrate for receiving a semiconductor device, comprising:
a support according to claim 1; and
a seed layer transferred onto the first front face of the support.

9. The substrate of claim 8, wherein the seed layer comprises gallium nitride, silicon carbide, sapphire or silicon (1,1,1).

10. The substrate of claim 8, further comprising a dielectric bonding layer disposed between, and in contact with, the support and the seed layer.

11. The substrate of claim 8, wherein the seed layer is in direct contact with the support.

12. The substrate of claim 8, further comprising a gallium nitride-based buffer layer disposed on the seed layer.

13. The substrate of claim 12, wherein the buffer layer is more than 3 microns thick.

14. The substrate of claim 8, further comprising a heterojunction disposed on the buffer layer, the heterojunction comprising a channel layer and a barrier layer and being capable of forming a 2D electron gas.

15. A semiconductor component, comprising:
a substrate according to claim 14
a source structure, a drain structure and a gate structure disposed on the heterojunction.

16. The semiconductor component of claim 15, further comprising a metal sheet disposed under the second rear face of the substrate, the metal sheet in ohmic contact with the second surface layer.

17. The semiconductor component of claim 16, further comprising an adhesion layer disposed between the metal sheet and the second surface layer.

18. The semiconductor component of claim 16, further comprising a metal layer disposed against the second surface layer.

19. The substrate of claim 13, wherein the buffer layer is more than 5 microns thick.

20. The substrate of claim 19, wherein the buffer layer is between 5 microns and 10 microns thick.
